(19) United States
(12) Patent Application Publication
(10) Pub. No.: US 2020/0111720 A1
(43) Pub. Date: Apr. 9, 2020

(54) DUAL SIDE DIE PACKAGING FOR ENHANCED HEAT DISSIPATION

(71) Applicant: Intel Corporation, Santa Clara, CA (US)

(72) Inventors: Zhimin Wan, Chandler, AZ (US); Shankar Devasenathipathy, Tempe, AZ (US); Chia-Pin Chiu, Tempe, AZ (US); Chandra Mohan Jha, Chandler, AZ (US); Weihua Tang, Chandler, AZ (US)

(21) Appl. No.: 16/153,392

(22) Filed: Oct. 5, 2018

(51) Int. Cl. H01L 23/367; H01L 23/538; H01L 23/13; H01L 25/18; H01L 25/00; H01L 21/48

(52) U.S. Cl. CPC H01L 23/3675; H01L 23/5386; H01L 23/13; H01L 24/16; H01L 25/18; H01L 25/50; H01L 21/4875; H01L 23/5385

(57) ABSTRACT

An Integrated Circuit (IC) device structure is provided. The IC device structure includes a first substrate, first one or more dies coupled to a first side of the first substrate by a first plurality of interconnect structures, second one or more dies coupled to a first section of a second side of the substrate by a second plurality of interconnect structures, and a third plurality of interconnect structures to couple a second section of the second side of the substrate to a second substrate. In an example, at least a part of the second one or more dies are within a cavity in the second substrate.

### BACKGROUND

Integrated Circuit (IC) device structures are decreasing in size, while becoming more powerful. This has provided a thermal challenge. For example, when two dies are proximally placed, heat generated by a first die can spread to a proximally placed second die, resulting in thermal cross-talk between the two dies. This may adversely affect thermal management of the two dies.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A schematically illustrates a cross-sectional view of an IC device structure that includes a first component on a first side of a first substrate, and a second component on a second side of the first substrate, wherein the second component is at least in part within a cavity of a second substrate, according to some embodiments.

FIG. 1B illustrates a top view of the device of FIG. 1A, according to some embodiments.

FIG. 2 illustrates an example implementation of the second component of the device of FIG. 1A, according to some embodiments.

FIG. 3 schematically illustrates a cross-sectional view of an IC device structure that includes a first component on a first side of a first substrate, a second component on a second side of the first substrate, and heat spreaders attached to the first and second components, wherein the second component is at least in part within a cavity of a second substrate, according to some embodiments.

FIG. 4 schematically illustrates a cross-sectional view of an IC device structure that includes a first component on a first side of a first substrate, and a second component on a second side of the first substrate, wherein the second component is at least in part within a cavity of a second substrate, and wherein the first component is not fully off-centered with respect to the second component, according to some embodiments.

FIG. 5 schematically illustrates a cross-sectional view of an IC device structure that includes a first component on a first side of a first substrate, and a second component on a second side of the first substrate, wherein the second component is at least in part within a cavity of a second substrate, and wherein the device includes cooling arrangements attached to heat spreaders of the device, according to some embodiments.

FIG. 6 schematically illustrates a cross-sectional view of an IC device structure that includes a first component on a first side of a first substrate, and a second component on a second side of the first substrate, wherein the second component is at least in part within a cavity of a second substrate, and wherein the second substrate is coupled to a circuit board, according to some embodiments.

FIGS. 7A, 7B, 7C, 7D, 7E, 7F, 7G, and 7H illustrate example processes for formation of an IC device structure that includes a first component on a first side of a first substrate, and a second component on a second side of the first substrate, wherein the second component is at least in part within a cavity of a second substrate, according to some embodiments.

FIG. 8 illustrates a flowchart depicting a method for forming an IC device structure that includes a first component on a first side of a first substrate, and a second component on a second side of the first substrate, wherein the second component is at least in part within a cavity of a second substrate, according to some embodiments.

FIG. 9 illustrates a computer system, a computing device or a SoC (System-on-Chip), where one or more components of the computing device are included in an IC device structure that includes a first component on a first side of a first substrate, and a second component on a second side of the first substrate, wherein the second component is at least in part within a cavity of a second substrate, according to some embodiments.

### DETAILED DESCRIPTION

In an example, in an Integrated Circuit (IC) device structure, one or more first dies and one or more second dies are separated by a first substrate. For example, the one or more first dies are formed on a first side of the first substrate, and the one or more second dies are formed on an opposing second side of the first substrate. The one or more first dies and the one or more second dies are electrically coupled through interconnect bridge structures embedded within the first substrate. A first heat spreader is coupled to the first die, and a second heat spreader is coupled to the second one or more dies.

The first substrate is coupled to a second substrate. In an example, the second substrate is a circuit board, e.g., a mother board, a printed circuit board (PCB), etc., although in another example the second substrate may not be a circuit board.

In some embodiments, the second substrate has a recess or cavity. In an example, the cavity is a through hole cavity. The one or more second dies are at least in part within the cavity of the second substrate. For example, a first surface of the one or more second dies is coupled to the first substrate, a second surface of the one or more second dies is coupled to the second heat spreader, and the one or more second dies is within the through hole cavity of the second substrate.

In an example, having the one or more first dies on a first side of the first substrate and the one or more second dies on a second side of the first substrate thermally isolates the first die and the one or more second dies. For example, heat from the first die cannot travel and cannot adversely affect the one or more second dies, thereby preventing thermal cross-talk between the first die and the one or more second dies. Other technical effects will be evident from the various embodiments and figures.

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” or “some embodiments” means that a particular feature, structure, function, or characteristic described in connection with the embodiment is included in at least one embodiment of the invention. Thus, the appearances of the phrase “in an embodiment” or “in one embodiment” or “some embodiments” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

It is pointed out that those elements of the figures having the same reference numbers (or names) as the elements of any other figure can operate or function in any manner similar to that described, but are not limited to such.

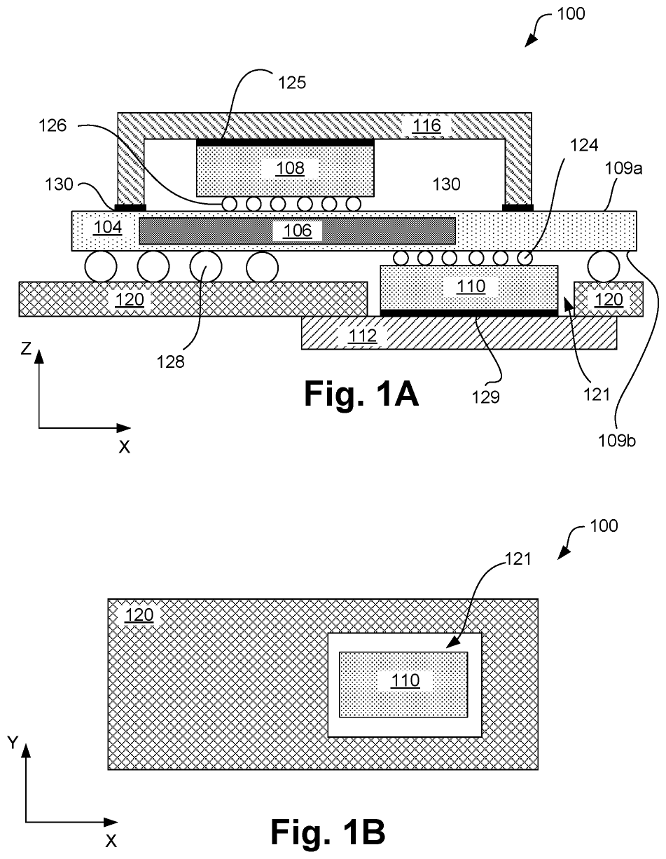

FIG. 1A schematically illustrates a cross-sectional view (e.g., along X-Z axis) of an IC device structure 100 (also referred to herein as device 100) that includes a first component 108 on a first side 109a of a first substrate 104, and a second component 110 on a second side 109b of the first substrate 104, wherein the second component 110 is at least in part within a cavity 121 of a second substrate 120, according to some embodiments.

Individual ones of the components 108, 110 can be any electronic device or component that may be included in an IC device, e.g., an IC die, a chip, a processor, a Central Processing Unit (CPU), a Graphics Processing Unit (GPU), a computer memory, a platform controller hub, etc. In some embodiments, individual ones of the components 108, 110 is a discrete chip, or a stack or group of chips. The components 108, 110 may include, or be a part of, a processor, memory, or application specific integrated circuit (ASIC), for example. Although merely two components 108, 110 are illustrated, the device 100 may include any other appropriate number of such components. In an example and as discussed herein in further details, the component 110 and/or the component 108 may include a plurality of stacked IC dies.

The device 100 includes the substrates 104, 120. In some embodiments, the substrate 120 is a circuit board, e.g., a PCB, a motherboard, etc. In some other embodiments, the device 100 is coupled to a circuit board that is not illustrated in FIG. 1A (e.g., in such embodiments, the substrate 120 is not a circuit board).

A substrate discussed herein, such as one or both the substrates 104, 120, may electrically couple an electrical component (e.g., one or more IC dies) and a next-level component to which an IC package (e.g., a circuit board) is coupled. In an example, a substrate may include any suitable type of substrate capable of providing electrical communication between an IC die and an upper IC package coupled with a lower IC/die package. In an example, a substrate may include any suitable type of substrate capable of providing electrical communication between an upper IC package and a next-level component to which an IC package is coupled. A substrate may also provide structural support for a die. By way of example, in one embodiment, a substrate may comprise a multi-layer substrate—including alternating layers of a dielectric material and metal built-up around a core layer (either a dielectric core or a metal core). In another embodiment, a substrate may be a coreless multi-layer substrate. Other types of substrates and substrate materials may also be used (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases). In an example, a substrate is a cored or coreless package substrate, may include epoxy resins, FR4, one or more semiconductor interposers (e.g., silicon), etc. A substrate may be formed of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, such as can be used in printed circuit boards (PCBs).

The component 108 is coupled to the substrate 104 (e.g., to the first side 109a of the substrate) using interconnect structures 126. The component 110 is coupled to the substrate 104 (e.g., to the second side 109b of the substrate 104) using interconnect structures 124. In some embodiments, the substrate 104 (e.g., the second side 109b of the substrate) is coupled to the substrate 120 using interconnect structures 128. Thus, a first section of the side 109b of the substrate 104 is coupled to the substrate 120 by the interconnect structures 128, and a second section of the side 109b of the substrate 104 is coupled to the component 110 by the interconnect structures 124.

The interconnect structures 126, 124, 128, for example, are bumps, bump pads, metal pillars (e.g., copper pillars), balls formed using metals, alloys, solderable material, or the like. For example, the interconnect structures 124, 126, 128 are bumps, balls, and/or solder formed using metals, alloys, solderable material, and/or the like.

The interconnect structures 126 are configured to route electrical signals between the component 108 and the substrate 104. The interconnect structures 124 are configured to route electrical signals between the component 110 and the substrate 104. The interconnect structures 128 are configured to route electrical signals between the substrate 104 and the substrate 120.

In some embodiments, the substrate 104 routes signals between the components 108, 110. For example, the substrate 104 acts as an interposer or an interconnect bridge between the components 108, 110. For example, an interconnect bridge 106 (merely symbolically illustrated as a rectangular box in FIG. 1A) is embedded within the substrate 104, where the interconnect bridge 106 facilitates signal communication between the components 108, 110. Merely as an example, the interconnect bridge 106 may be an Embedded Multi-Die Interconnect Bridge (EMIB) developed by INTEL®, or the like.

In some embodiments, the substrate 120 includes a cavity 121, and the component 110 is at least in part within the cavity 121. FIG. 1B illustrates a top view (e.g., along X-Y axis) of the device 100, according to some embodiments. In the example of FIG. 1B, for purposes of clarity, merely the substrate 120, the cavity 121, and the components 110 are illustrated, without illustrating various other elements of the device 100. As illustrated in FIGS. 1A-1B, the cavity 121 may be a through hole in the substrate 120, e.g., extending from a first surface 105a of the substrate 120 to an opposing second surface 105b of the substrate 120.

Referring again to FIG. 1A, the device 100 comprises a heat spreader 116 coupled to the component 108. For example, a first side of the component 108 is coupled to the substrate 104, and an opposing second side of the component 108 is coupled to the heat spreader 116. In an example, the heat spreader 116 includes thermally conductive material, such as metal (e.g., copper).

In an example, the component 108 is coupled to the heat spreader 116 by a material 125, where the material 125 may be thermally conductive material. For example, the material 125 may be Thermal Interface Material (TIM). The material 125 may be, for example, thermal grease, thermal adhesive, thermal gap filler, thermally conductive pad, thermal tape, solder, and/or the like.

In an example, the heat spreader 116 may be an Integrated Heat Spreader (IHS). The heat spreader 116 may have a first section coupled to the component 108, a second section coupled to the substrate 104 (e.g., through a material 130, which may be a thermally conductive sealant or TIM), and a third section coupled to the substrate 104 (e.g., through the material 130). Although not illustrated in FIGS. 1A-1B, the device 100 may include appropriate arrangements to transport the heat from the heat spreader 116 to the ambient, such as air cooling arrangement, liquid cooling arrangement, fins, etc.

In some embodiments, the device 100 comprises a heat spreader 112 coupled to the component 110. For example, a first side of the component 110 is coupled to the substrate 104, and an opposing second side of the component 110 is coupled to the heat spreader 112. In an example, the heat spreader 112 includes thermally conductive material, such as metal (e.g., copper).

In an example, the component 110 is coupled to the heat spreader 112 by a material 129, where the material 129 may be thermally conductive material. For example, the material 129 may be a TIM. The material 129 may be, for example, thermal grease, thermal adhesive, thermal gap filler, thermally conductive pad, thermal tape, solder, and/or the like.

In an example, the heat spreader 112 may be an IHS, a heat sink, and/or the like. Although not illustrated in FIGS. 1A-1B, the device 100 may include appropriate arrangements to transport the heat from the heat spreader 112 to the ambient, such as air cooling arrangement, liquid cooling arrangement, fins, etc.

In some embodiments and as illustrated in FIG. 1A, a bottom surface of the component 110 (e.g., the surface of the component 110 coupled to the heat spreader 112) may be substantially coplanar with a bottom surface of the substrate 120 (e.g., where a top surface of the substrate 120 is coupled to the substrate 104, and the bottom surface of the substrate 120 is opposite the top surface). In some other embodiments and contrary to the illustration of FIG. 1A, the bottom surface of the component 110 may not be coplanar with the bottom surface of the substrate 120.

In some embodiments, the heat spreader 112 may be coupled to at least a section of the bottom surface of the substrate 120. Thus, a first section of the heat spreader 112 may be coupled to the bottom surface of the component 110, and a second section of the heat spreader 112 may be coupled to the bottom surface of the substrate 120. However, in some other embodiments (and contrary to the illustration of FIG. 1A), the heat spreader 112 may be coupled to the bottom surface of the component 110 through material 129, and not coupled to the bottom surface of the substrate 120.

In some embodiments, heat generated by the component 108 may be removed by the heat spreader 116, while the heat generated by the component 110 may be removed by the heat spreader 112. As the components 110, 108 are separated by the substrate 104, heat from the component 108 may not reach component 110, and may not adversely affect the operation of the component 110, thereby preventing thermal cross-talk between the components 108 and 110.

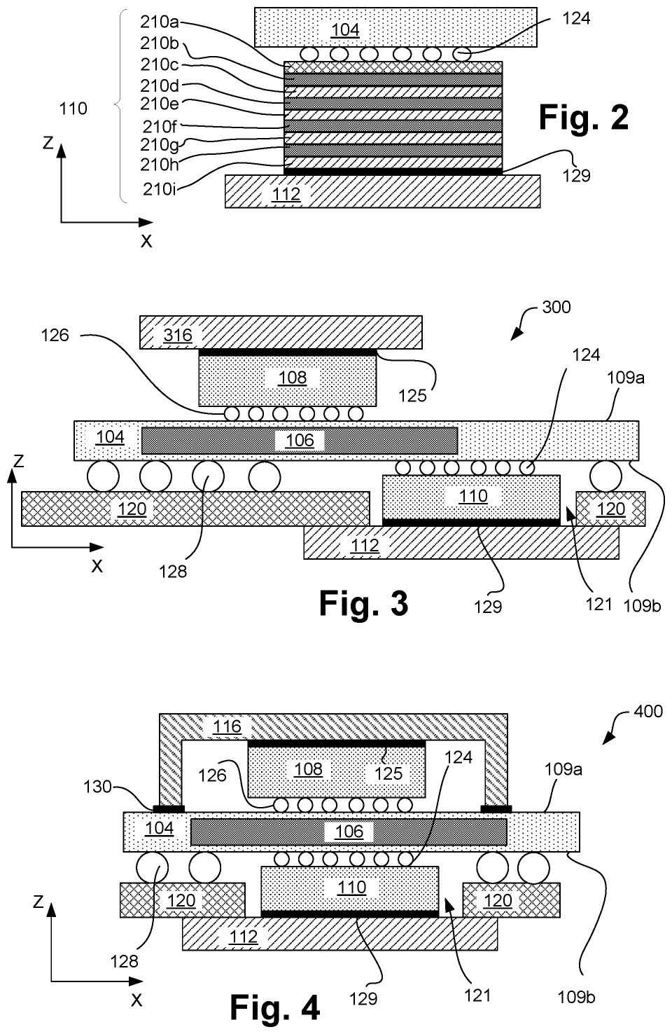

FIG. 2 illustrates an example implementation of the component 110 of the device 100 of FIGS. 1A-1B, according to some embodiments. In the example of FIG. 2, the components 110 includes a stack of components 210a, 210b, . . . , 210i, where a top surface of the stack is coupled to the substrate 104 by the interconnect structures 124, and a bottom surface of the stack is coupled to the heat spreader 112 by the material 129.

In some embodiments, the component 110 includes a stack of memory dies, e.g., the component 110 forms a High-Bandwidth memory (HBM). For example, the component 210a is a logic die, which may include logic circuitry (e.g., a memory controller) to facilitate communication between the components 108 and 110. The components 210b, 210c, . . . , 210i may be memory dies arranged in a stack. For the sake of clarity and to not obfuscate the principles of this disclosure, various elements of the components are not illustrated in FIG. 2, e.g., interconnect structures between the components 210a, . . . , 210i, dielectric layers between these components, through silicon vias (TSVs) that facilitate communication between the stack of dies, etc.

In some embodiments, the component 110 includes a plurality of stacked memory dies (e.g., as discussed above with respect to FIG. 2), and the component 108 includes a processor, a CPU, a GPU, etc.

FIG. 3 schematically illustrates a cross-sectional view (e.g., along X-Z axis) of an IC device structure 300 (also referred to herein as device 300) that includes the first component 108 on the first side 109a of the first substrate 104, and the second component 110 on the second side 109b of the first substrate 104, wherein the second component 110 is at least in part within the cavity 121 of the second substrate 120, and wherein a heat spreader 316 is not attached to the first substrate 104, according to some embodiments. The device 300 is at least in part similar to the device 100, and similar components in these two devices 100, 300 are labelled using similar labels. However, in the device 300, the heat spreader 316 is different from the heat spreader 116 of the device 100. For example, unlike FIGS. 1A-1B, in FIG. 3 the heat spreader 316 may not be coupled to the substrate 104.

FIG. 4 schematically illustrates a cross-sectional view (e.g., along X-Z axis) of an IC device structure 400 (also referred to herein as device 400) that includes the first component 108 on the first side 109a of the first substrate 104, and the second component 110 on the second side 109b of the first substrate 104, wherein the second component 110 is at least in part within the cavity 121 of the second substrate 120, and wherein the first component 108 is not fully off-centered with respect to the second component 110, according to some embodiments. The device 400 is at least in part similar to the device 100, and similar components in these two devices 100, 400 are labelled using similar labels.

In FIG. 4, a position of the component 110 is different from that of FIG. 1. For example, in FIGS. 1A-1B, the components 108 and 110 are offset, or off-centered, with respect to each other. However, in FIG. 4, the components 110 and 108 are not as off-centered as in FIG. 1. For example, in FIG. 4, the components 110 and 108 are substantially aligned.

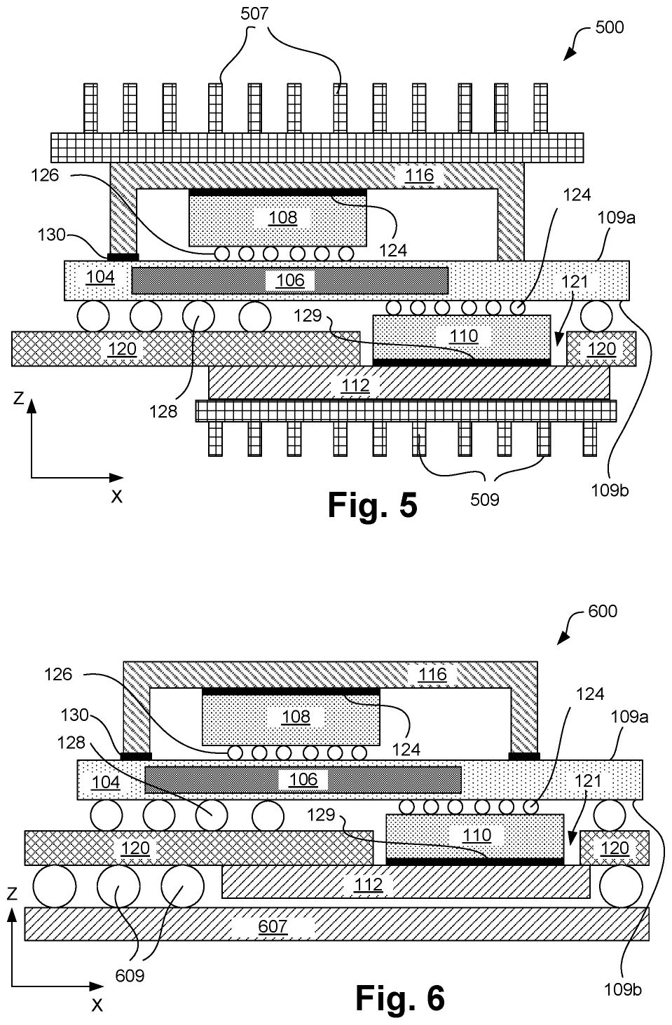

FIG. 5 schematically illustrates a cross-sectional view (e.g., along X-Z axis) of an IC device structure 500 (also referred to herein as device 500) that includes the first component 108 on the first side 109a of the first substrate 104, and the second component 110 on the second side 109b of the first substrate 104, wherein the second component 110 is at least in part within the cavity 121 of the second substrate 120, and wherein the device 500 includes cooling arrangements attached to the heat spreaders 112, 116, according to some embodiments. The device 500 is at least in part similar to the device 100, and similar components in these two devices 100, 500 are labelled using similar labels.

In the device 500, in some embodiments, a plurality of extensions or fins 507 are attached to the heat spreader 116, and a plurality of extensions or fins 509 are attached to the heat spreader 112. The fins 507, 509 may dissipate heat to the ambient. In an example, forced air may be circulated through the fins 507, 509, e.g., to dissipate heat more effectively from the fins 507, 509. The fins 509 may be attached to the heat spreader 112 through a heat sink base 511. For example, the fins 509 may be attached to the heat sink base 511, and the heat sink base 510 may be attached to the heat spreader 112. The fins 507 may be attached to the heat spreader 116 through a heat sink base 510. For example, the fins 507 may be attached to the heat sink base 510, and the heat sink base 510 may be attached to the heat spreader 116.

FIG. 6 schematically illustrates a cross-sectional view (e.g., along X-Z axis) of an IC device structure 600 (also referred to herein as device 600) that includes the first component 108 on the first side 109a of the first substrate 104, and the second component 110 on the second side 109b of the first substrate 104, wherein the second component 110 is at least in part within the cavity 121 of the second substrate 120, and wherein the second substrate 120 is coupled to a circuit board 607, according to some embodiments. The device 600 is at least in part similar to the device 100, and similar components in these two devices 100, 600 are labelled using similar labels.

As discussed with respect to FIGS. 1A-1B, the substrate 120 may be a circuit board in some examples. However, in the example of FIG. 6, the substrate 120 may not be a circuit board, and the substrate 120 may be coupled to a circuit board 607 (e.g., a PCB, a motherboard, etc.) using interconnect structures 609.

A bottom surface of the heat spreader 112 is illustrated in FIG. 6 to be separated from the circuit board 607. However, in an example and contrary to the illustration of FIG. 6, the bottom surface of the heat spreader 112 may be coupled to the circuit board 607 through interconnect structures (e.g., for thermally coupling the heat spreader 112 to the circuit board 607), thermal interface material, thermally conductive adhesive, etc.

FIGS. 1A-6 illustrate various features of an IC device structure. Features from two or more of these figures may be combined in some embodiments. Merely as an example, combining FIGS. 4 and 5 would result in an IC device structure that has fins attached to the heat spreaders 112, 116, and that has the components 110, 108 substantially aligned or centered.

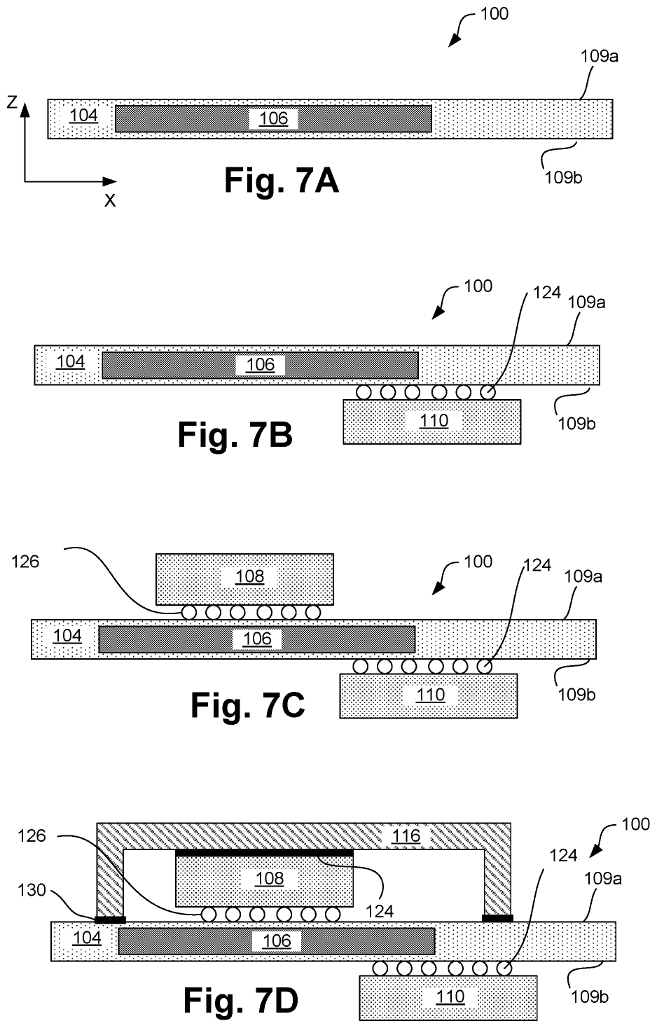

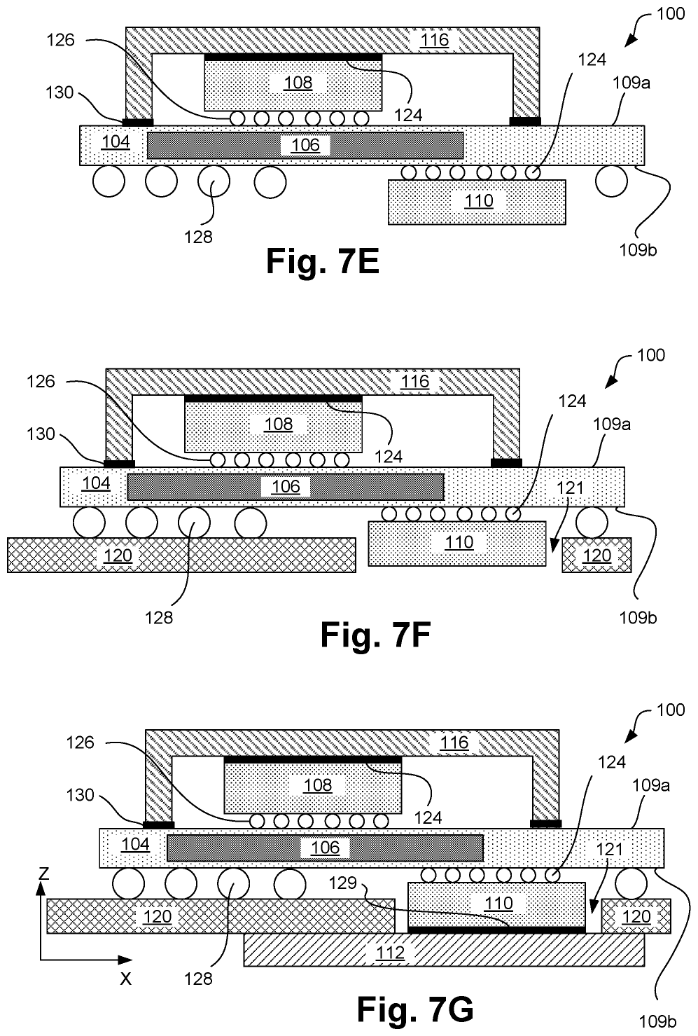

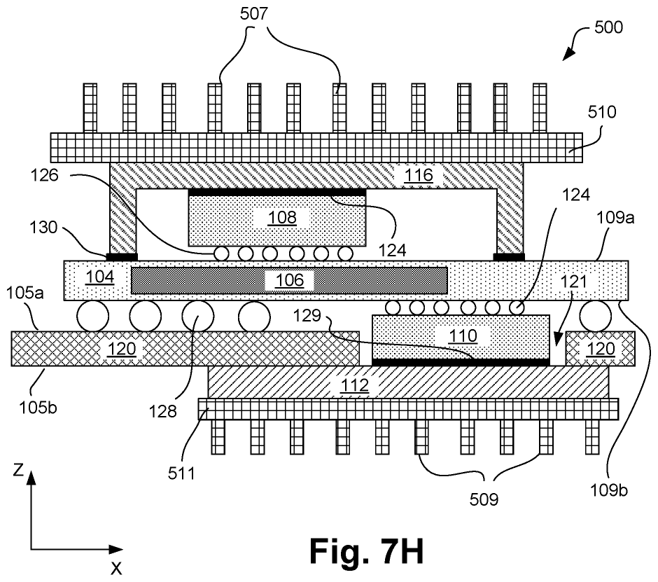

FIGS. 7A, 7B, 7C, 7D, 7E, 7F, 7G, and 7H illustrate example processes for formation of an IC device structure (e.g., the device 100 of FIGS. 1A-1B, or the device 500 of FIG. 5) that includes the first component 108 on the first side 109a of the first substrate 104, and the second component 110 on the second side 109b of the first substrate 104, wherein the second component 110 is at least in part within the cavity 121 of the second substrate 120, according to some embodiments. For example, FIGS. 7A-7G are cross-sectional views (e.g., along X-Z planes) of the package 100 evolving as example operations for formation of the package 100 are performed.

Referring to FIG. 7A, the substrate 104 is provided. The substrate 104 includes embedded interconnect structures, e.g., to couple the components 108, 110. For example, the interconnect bridge 106 is embedded within the substrate 104. The substrate has opposing surfaces 109a, 109b.

Referring now to FIG. 7B, the component 110 is coupled to the substrate 104 (e.g., to the surface 109b of the substrate 104) using interconnect structures 124. Although not illustrated, underfill material may be formed between the component 110 and the substrate 104, e.g., surrounding the interconnect structures 124.

Referring now to FIG. 7C, the component 108 is coupled to the substrate 104 (e.g., to the surface 109a of the substrate 104) using interconnect structures 126. Although not illustrated, underfill material may be formed between the component 108 and the substrate 104, e.g., surrounding the interconnect structures 126.

Referring now to FIG. 7D, material 124 is applied to the top surface of the component 108, and the heat spreader 116 is coupled to the component 108 through the material 124.

Referring now to FIG. 7E, interconnect structures 128 are coupled to the substrate 104 (e.g., coupled to the surface 109b of the substrate 104). Thus, for example, a first section of the surface 109b of the substrate 104 is coupled to the interconnect structures 124, and a second section of the surface 109b of the substrate 104 is coupled to the interconnect structures 128.

Referring now to FIG. 7F, the substrate 120 is provided, where the substrate 120 has the cavity 121. The structure of FIG. 7E is surface mounted on the substrate 120, such that the component 110 is at least in part within the cavity 121. The substrate 104 is coupled to the substrate 120 by the interconnect structures 128.

Referring now to FIG. 7G, material 129 is applied to the bottom surface of the component 110, and the heat spreader 112 is coupled to the component 110 via the material 129. The device of FIG. 7G is the device 100 of FIG. 1.

Referring now to FIG. 7H, fins 507, 509 are respectively attached to the heat spreaders 116, 112, to form the device 500 of FIG. 5.

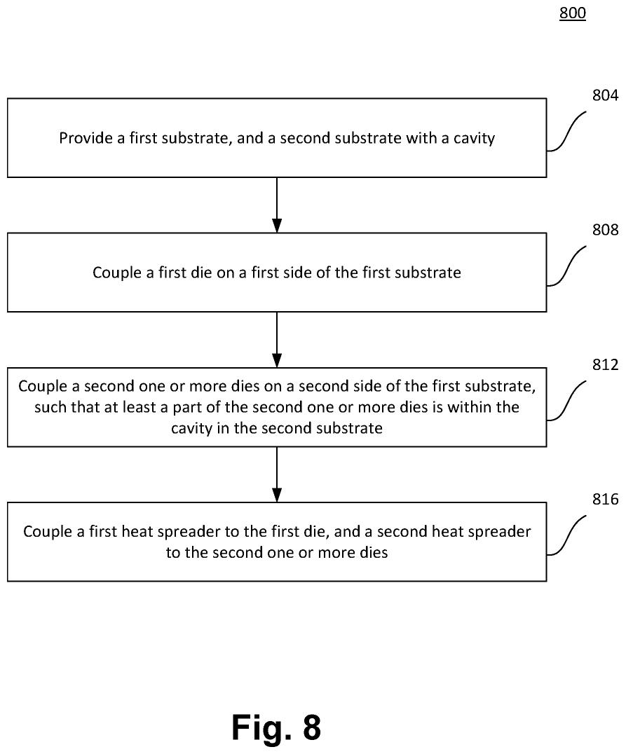

FIG. 8 illustrates a flowchart depicting a method 800 for forming an IC device structure (e.g., any one of the devices discussed with respect to FIGS. 1-7H) that includes a first component on a first side of a first substrate, and a second component on a second side of the first substrate, wherein the second component is at least in part within a cavity of a second substrate, according to some embodiments. Although the blocks in the flowchart with reference to FIG. 8 are shown in a particular order, the order of the actions can be modified. Thus, the illustrated embodiments can be performed in a different order, and some actions/blocks may be performed in parallel. Some of the blocks and/or operations listed in FIG. 8 may be optional in accordance with certain embodiments. The numbering of the blocks presented is for the sake of clarity and is not intended to prescribe an order of operations in which the various blocks must occur.

The method 800 includes, at 804, providing a first substrate (e.g., substrate 104), and a second substrate (e.g., substrate 120) with a cavity (e.g., cavity 121), e.g., as also discussed with respect to FIGS. 7A and 7F.

At 808, a first die (e.g., component 108) is coupled to a first side (e.g., to the side 109a) of the first substrate, e.g., as also discussed with respect to FIG. 7C. At 812, a second one or more dies (e.g., components 110) are coupled to a second side (e.g., to the side 109b) of the first substrate, such that at least a part of the second one or more dies is within the cavity in the second substrate.

At 816, a first heat spreader (e.g., heat spreader 116) is coupled to the first die, e.g., as discussed with respect to FIG. 7D. Also at 816, a second heat spreader (e.g., heat spreader 112) is coupled to the second one or more dies, e.g., as discussed with respect to FIG. 7G.

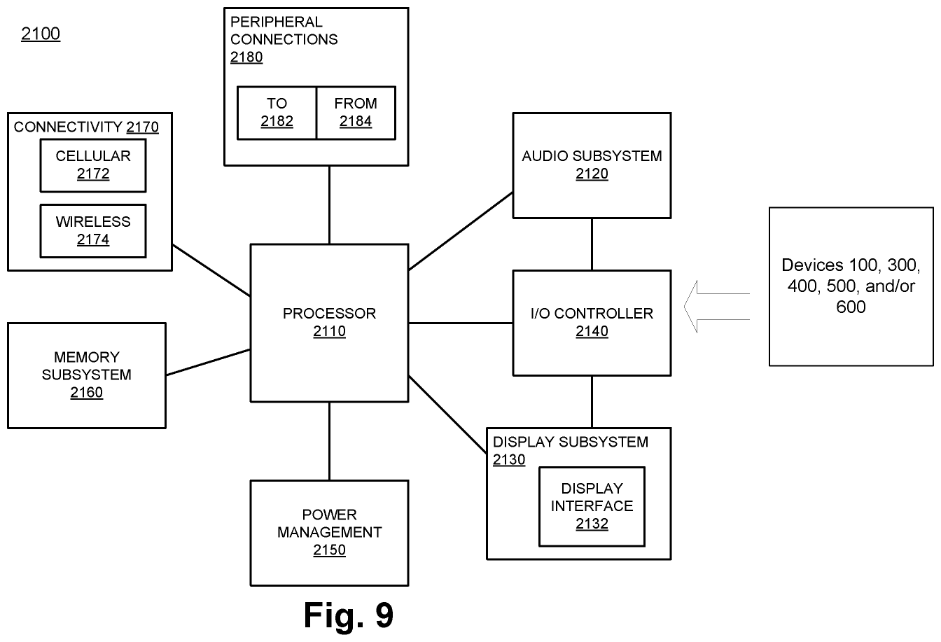

FIG. 9 illustrates a computer system, a computing device or a SoC (System-on-Chip) 2100, where one or more components of the computing device 2100 are included in an IC device structure (e.g., any one of the devices discussed with respect to FIGS. 1-8) that includes a first component on a first side of a first substrate, and a second component on a second side of the first substrate, wherein the second component is at least in part within a cavity of a second substrate, according to some embodiments. It is pointed out that those elements of FIG. 9 having the same reference numbers (or names) as the elements of any other figure can operate or function in any manner similar to that described, but are not limited to such.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100. In one embodiment, computing device 2100 includes a clock generation subsystem 2152 to generate a clock signal.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, one or more components of the computing device 2100 may be included in any of the IC device structure discussed herein (e.g., any one of the devices 100, 300, 400, 500, and/or 600 discussed with respect to FIGS. 1-8). In an example, a processor, a CPU, a GPU, and/or the like of the computing device 2100 may be included in the component 108. In an example, a memory of the computing device 2100 may be included in the component 110.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

Example 1. An Integrated Circuit (IC) device structure comprising: a first substrate; first one or more dies coupled to a first side of the first substrate by a first plurality of interconnect structures; second one or more dies coupled to a first section of a second side of the first substrate by a second plurality of interconnect structures, the second side being opposite the first side; and a third plurality of interconnect structures to couple a second section of the second side of the first substrate to a second substrate, wherein at least a part of the second one or more dies are within a cavity in the second substrate.

Example 2. The IC device structure of example 1 or any other examples, wherein: a first surface of the second one or more dies is coupled to the first substrate by the second plurality of interconnect structures, and a second surface of the second one or more dies is opposite the first surface; a first surface of the second substrate is coupled to the first substrate by the third plurality of interconnect structures, and a second surface of the second substrate is opposite the first surface; and the second surface of the second one or more dies is substantially coplanar with the second surface of the second substrate.

Example 3. The IC device structure of example 1 or any other examples, wherein: the cavity in the second substrate is a through hole that extends from a first surface of the second substrate to an opposing second surface of the second substrate.

Example 4. The IC device structure of example 1 or any other examples, further comprising: a heat sink coupled to the second one or more dies.

Example 5. The IC device structure of example 4 or any other examples, wherein: a first surface of the second one or more dies is proximal to the first substrate than an opposing second surface of the second one or more dies; a first surface of the second substrate is proximal to the first substrate than an opposing second surface of the second substrate; a first section of the heat sink is coupled to the second surface of the second one or more dies; and a second section of the heat sink is coupled to the second surface of the second substrate.

Example 6. The IC device structure of example 1 or any other examples, wherein: a first surface of the first one or more dies is proximal to the first substrate than an opposing second surface of the first one or more dies; and the IC device structure comprises a heat spreader coupled to the second surface of the first one or more dies.

Example 7. The IC device structure of example 6 or any other examples, wherein: a first section of the heat spreader is coupled to the second surface of the first one or more dies; and a second section of the heat spreader is coupled to the first substrate.

Example 8. The IC device structure of example 1 or any other examples, comprising: a plurality of interconnect layers embedded within the first substrate and to electrically couple the first one or more dies and the second one or more dies.

Example 9. The IC device structure of example 1 or any other examples, wherein: the second substrate is a circuit board.

Example 10. The IC device structure of example 1 or any other examples, comprising: a fourth plurality of interconnect structures to couple the second substrate to a circuit board.

Example 11. The IC device structure of example 1 or any other examples, wherein: the first one or more dies comprises one or more processing cores.

Example 12. The IC device structure of example 1 or any other examples, wherein: the second one or more dies comprises a plurality of dies arranged in a stack and coupled to the first substrate.

Example 13. The IC device structure of example 1 or any other examples, wherein the second one or more dies comprises: a plurality of memory dies; and a logic die to facilitate communication between the plurality of memory dies and the first one or more dies, wherein the logic die and the plurality of memory dies are arranged in a stack, such that the logic die is between the first substrate and the plurality of memory dies.

Example 14. A system comprising: a memory to store instructions; a processor to execute the instructions; a first substrate; a second substrate having a through hole; first one or more dies coupled to a first side of the first substrate by a first plurality of interconnect structures; second one or more dies coupled to a first section of a second side of the first substrate by a second plurality of interconnect structures; and a third plurality of interconnect structures to couple a second section of the second side of the first substrate to the second substrate, wherein at least a part of the second one or more dies is within the through hole of the second substrate, wherein at least one of the memory of the processor is included in at least one of: the first one or more dies or the second one or more dies.

Example 15. The system of example 14 or any other examples, wherein: the system comprises a power supply to supply power to at least one of the first one or more dies or the second one or more dies; the second one or more dies comprises the memory; the first one or more dies comprises the processor; and the system comprises a wireless interface to facilitate the system to communicate with another system.

Example 16. The system of example 14 or any other examples, comprising: a first heat spreader coupled to the first one or more dies; and a second heat spreader coupled to the second one or more dies.

Example 17. The system of example 14 or any other examples, comprising: a plurality of interconnect layers embedded within the first substrate, the plurality of interconnect layers to electrically couple the first one or more dies and the second one or more dies.

Example 18. A method comprising: providing a first substrate, and a second substrate with a cavity; coupling a first die to a first side of the first substrate; and coupling a second one or more dies to a second side of the first substrate, the second side being opposite the first side, such that at least a part of the second one or more dies is within the cavity in the second substrate.

Example 19. The method of example 18 or any other examples, further comprising: coupling a first heat spreader to the first die, and a second heat spreader to the second one or more dies.

Example 20. The method of example 19 or any other examples, further comprising: coupling the second heat spreader to the second substrate.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An Integrated Circuit (IC) device structure comprising:
a first substrate;
first one or more dies coupled to a first side of the first substrate by a first plurality of interconnect structures;
second one or more dies coupled to a first section of a second side of the first substrate by a second plurality of interconnect structures, the second side being opposite the first side; and
a third plurality of interconnect structures to couple a second section of the second side of the first substrate to a second substrate,
wherein at least a part of the second one or more dies are within a cavity in the second substrate.

2. The IC device structure of claim 1, wherein:
a first surface of the second one or more dies is coupled to the first substrate by the second plurality of interconnect structures, and a second surface of the second one or more dies is opposite the first surface;
a first surface of the second substrate is coupled to the first substrate by the third plurality of interconnect structures, and a second surface of the second substrate is opposite the first surface; and
the second surface of the second one or more dies is substantially coplanar with the second surface of the second substrate.

3. The IC device structure of claim 1, wherein:
the cavity in the second substrate is a through hole that extends from a first surface of the second substrate to an opposing second surface of the second substrate.

4. The IC device structure of claim 1, further comprising:
a heat sink coupled to the second one or more dies.

5. The IC device structure of claim 4, wherein:
a first surface of the second one or more dies is proximal to the first substrate than an opposing second surface of the second one or more dies;
a first surface of the second substrate is proximal to the first substrate than an opposing second surface of the second substrate;
a first section of the heat sink is coupled to the second surface of the second one or more dies; and
a second section of the heat sink is coupled to the second surface of the second substrate.

6. The IC device structure of claim 1, wherein:
a first surface of the first one or more dies is proximal to the first substrate than an opposing second surface of the first one or more dies; and
the IC device structure comprises a heat spreader coupled to the second surface of the first one or more dies.

7. The IC device structure of claim 6, wherein:
a first section of the heat spreader is coupled to the second surface of the first one or more dies; and
a second section of the heat spreader is coupled to the first substrate.

8. The IC device structure of claim 1, comprising:
a plurality of interconnect layers embedded within the first substrate and to electrically couple the first one or more dies and the second one or more dies.

9. The IC device structure of claim 1, wherein:
the second substrate is a circuit board.

10. The IC device structure of claim 1, comprising:
a fourth plurality of interconnect structures to couple the second substrate to a circuit board.

11. The IC device structure of claim 1, wherein:
the first one or more dies comprises one or more processing cores.

12. The IC device structure of claim 1, wherein:
the second one or more dies comprises a plurality of dies arranged in a stack and coupled to the first substrate.

13. The IC device structure of claim 1, wherein the second one or more dies comprises:
a plurality of memory dies; and
a logic die to facilitate communication between the plurality of memory dies and the first one or more dies,
wherein the logic die and the plurality of memory dies are arranged in a stack, such that the logic die is between the first substrate and the plurality of memory dies.

14. A system comprising:
a memory to store instructions;
a processor to execute the instructions;
a first substrate;
a second substrate having a through hole;
first one or more dies coupled to a first side of the first substrate by a first plurality of interconnect structures;
second one or more dies coupled to a first section of a second side of the first substrate by a second plurality of interconnect structures; and
a third plurality of interconnect structures to couple a second section of the second side of the first substrate to the second substrate, wherein at least a part of the second one or more dies is within the through hole of the second substrate,
wherein at least one of the memory of the processor is included in at least one of: the first one or more dies or the second one or more dies.

15. The system of claim 14, wherein:
the system comprises a power supply to supply power to at least one of the first one or more dies or the second one or more dies;
the second one or more dies comprises the memory;
the first one or more dies comprises the processor; and
the system comprises a wireless interface to facilitate the system to communicate with another system.

16. The system of claim 14, comprising:
a first heat spreader coupled to the first one or more dies; and
a second heat spreader coupled to the second one or more dies.

17. The system of claim 14, comprising:
a plurality of interconnect layers embedded within the first substrate, the plurality of interconnect layers to electrically couple the first one or more dies and the second one or more dies.

18. A method comprising:
providing a first substrate, and a second substrate with a cavity;
coupling a first die to a first side of the first substrate; and
coupling a second one or more dies to a second side of the first substrate, the second side being opposite the first side, such that at least a part of the second one or more dies is within the cavity in the second substrate.

19. The method of claim 18, further comprising:
coupling a first heat spreader to the first die, and a second heat spreader to the second one or more dies.

20. The method of claim 19, further comprising:
coupling the second heat spreader to the second substrate.
